(19) United States
(12) Patent Application Publication
(10) Pub. No.: US 2014/0117332 A1
(43) Pub. Date: May 1, 2014

(54) ORGANIC LIGHT EMITTING DEVICE

(71) Applicant: Samsung Display Co., Ltd., Yongin-City (KR)

(72) Inventor: Jae Young LEE, Yongin-City (KR)

(21) Appl. No.: 14/029,992

(22) Filed: Sep. 18, 2013

(30) Foreign Application Priority Data
Oct. 31, 2012 (KR) 10-2012-0122396

(51) Int. Cl. H01L 51/50

(52) U.S. Cl. CPC H01L 51/5064
USPC 257/40

(57) ABSTRACT

Provided is an organic light emitting device for which lifetime is increased by preventing its constituent hole transport layer from deteriorating due to introduction of electrons and excitons from its light emitting layer into the hole transport layer. The organic light emitting device includes a substrate, a first electrode formed on the substrate, a hole injection layer formed on the first electrode, a hole transport layer formed on the hole injection layer, a buffer layer formed on the hole transport layer, a light emitting layer formed on the buffer layer, an electron transport layer formed on the light emitting layer, an electron injection layer formed on the electron transport layer, a second electrode formed on the electron injection layer, and a blocking layer formed between the hole transport layer and the buffer layer so as to contact the hole transport layer and the buffer layer.

### CLAIM OF PRIORITY

This application makes reference to, incorporates the same herein, and claims all benefits accruing under 35 U.S.C. §119 from an application for ORGANIC LIGHT EMITTING DEVICE earlier filed in the Korean Intellectual Property Office on 31 Oct. 2012 and there duly assigned Serial No. 10-2012-0122396.

### BACKGROUND OF THE INVENTION

1. Field of the Invention

The present invention relates to an organic light emitting device, and more particularly, to an organic light emitting device for which increased lifetime may be achieved by preventing a hole transport layer from deteriorating due to introduction into the hole transport layer of electrons or excitons remaining in a light emitting layer.

2. Description of the Related Art

An organic light emitting device is a self-emitting light emitting device having high brightness, a wide viewing angle, excellent con and a quick response time. Moreover, the organic light emitting device has excellent driving voltage and response speed characteristics and can form multi-colored images.

A general organic light emitting device is configured such that an anode is formed on a substrate, and a hole injection layer, a hole transport layer, a light emitting layer, an electron transport layer, an electron injection layer and a cathode are sequentially stacked on the anode.

The aforementioned organic light emitting device is driven by the following principle. If a voltage is applied to the anode and the cathode, holes injected from the anode move toward the light emitting layer via the hole transport layer, and electrons injected from the cathode move toward the light emitting layer via the electron transport layer. Charge carriers such as the holes and electrons are recombined in the light emitting layer to generate excitons. When the excitons are converted from an excited state into a ground state, light is generated.

Meanwhile, in some cases, the electrons remaining in the light emitting layer after the excitons are formed or residual excitons may flow into the hole transport layer. In such cases, the hole transport layer may be deteriorated, resulting in a reduction in the lifetime of the organic light emitting device.

### SUMMARY OF THE INVENTION

The present invention provides an organic light emitting device for which lifetime may be increased by preventing a hole transport layer from deteriorating due to introduction into the hole transport layer of electrons or excitons remaining in a light emitting layer.

The above and other objects of the present invention will be described in or be apparent from the following description of the preferred embodiments.

According to an embodiment of the present invention, there is provided an organic light emitting device that includes a substrate, a first electrode formed on the substrate, a hole injection layer formed on the first electrode, a hole transport layer formed on the hole injection layer, a buffer layer formed on the hole transport layer, a light emitting layer formed on the buffer layer, an electron transport layer formed on the light emitting layer, an electron injection layer formed on the electron transport layer, a second electrode formed on the electron injection layer, and a blocking layer formed between the hole transport layer and the buffer layer so as to contact the hole transport layer and the buffer layer.

The blocking layer may include a p-type dopant.

A lowest unoccupied molecular orbital (LUMO) energy level of the p-type dopant may be higher than a highest occupied molecular orbital (HOMO) energy level of the hole transport layer or a highest occupied molecular orbital (HOMO) energy level of the light emitting layer, and the HOMO energy level of the light emitting layer may be higher than the HOMO energy level of the hole transport layer.

The blocking layer may be formed by doping the p-type dopant into the buffer layer.

The p-type dopant may be contained in an amount of 1 to 50% relative to an amount of a host contained in the blocking layer, and the host contained in the blocking layer may be a material for forming the buffer layer.

The blocking layer may be configured by forming the p-type dopant as a single layer and may be interposed between the buffer layer and the hole transport layer.

The blocking layer may have a thickness in a range of from about 10 Å to about 1000 Å.

The light emitting layer may be one of a red light emitting layer, a green light emitting layer, a blue light emitting layer and a white light emitting layer.

The white light emitting layer may be formed by stacking the red light emitting layer, the green light emitting layer and the blue light emitting layer.

According to another embodiment of the present invention, there is provided an organic light emitting device including a substrate, a first electrode formed on the substrate, a hole injection layer formed on the first electrode, a hole transport layer formed on the hole injection layer, a buffer layer formed on the hole transport layer, a light emitting layer formed on the buffer layer, an electron transport layer formed on the light emitting layer, an electron injection layer formed on the electron transport layer, and a second electrode formed on the electron injection layer, the hole transport layer including a blocking material.

The blocking material may be a p-type dopant.

A lowest unoccupied molecular orbital (LUMO) energy level of the p-type dopant may be higher than a highest occupied molecular orbital (HOMO) energy level of the hole transport layer or a highest occupied molecular orbital (HOMO) energy level of the light emitting layer, and the HOMO energy level of the light emitting layer may be higher than the HOMO energy level of the hole transport layer.

The light emitting layer may be one of a red light emitting layer, a green light emitting layer, a blue light emitting layer and a white light emitting layer.

The white light emitting layer may be formed by stacking the red light emitting layer, the green light emitting layer and the blue light emitting layer.

Embodiments of the present invention provide at least the following effects.

First, since the organic light emitting device according to an embodiment of the present invention includes a blocking layer formed between the hole transport layer and the buffer layer so as to contact the hole transport layer and the buffer layer, it is possible to prevent electrons remaining in the light emitting layer after the excitons are formed or residual excitons from flowing into the hole transport layer.

Alternatively, since the organic light emitting device according to an embodiment of the present invention includes a blocking material contained in the hole transport layer, it is possible to prevent the electrons remaining in the light emitting layer after the excitons are formed or residual excitons from flowing into the hole transport layer.

Therefore, in the organic light emitting device according to the present invention, deterioration of the hole transport layer due to remaining electrons or residual excitons may be avoided, thereby increasing the lifetime of the organic light emitting device.

### BRIEF DESCRIPTION OF THE DRAWINGS

The above and other features and advantages of the present invention will be made more apparent by describing in detail exemplary embodiments thereof with reference to the attached drawings in which:

FIG. 1 is a sectional view schematically illustrating an organic light emitting device according to an embodiment of the present invention;

FIG. 2 is an energy band diagram of the organic light emitting device shown in FIG. 1;

FIG. 3 is a graph illustrating results from measuring lifetime characteristics of the organic light emitting device shown in FIG. 1 and other organic light emitting devices;

FIG. 4 is a sectional view schematically illustrating an organic light emitting device according to another embodiment of the present invention; and

FIG. 5 is an energy band diagram of the organic light emitting device shown in FIG. 4.

### DETAILED DESCRIPTION OF THE INVENTION

It will be understood that when a layer is referred to as being “on” another layer or substrate, it can be directly on the other layer or substrate, or intervening layers may also be present. The same reference numbers indicate the same components throughout the specification.

Reference will now be made in detail to the present embodiments of the present invention, examples of which are illustrated in the accompanying drawings.

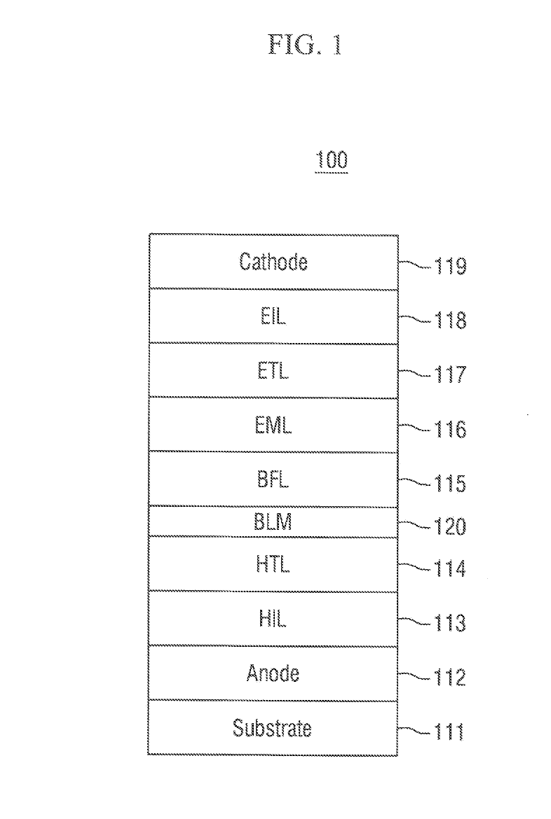

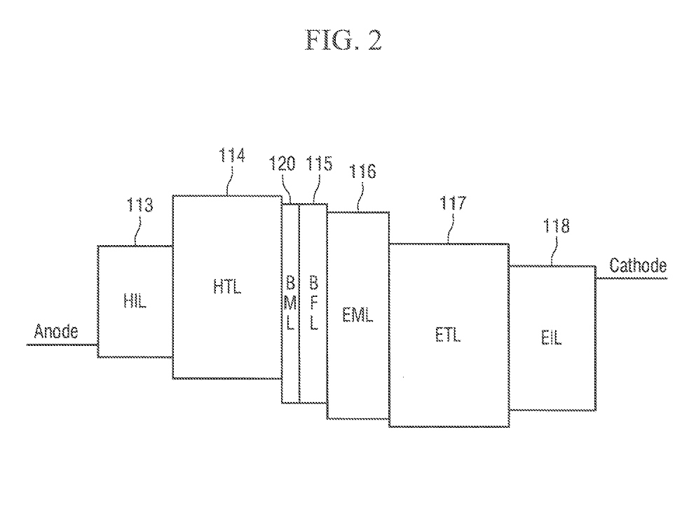

FIG. 1 is a sectional view schematically illustrating an organic light emitting device according to an embodiment of the present invention, and FIG. 2 is an energy band diagram of the organic light emitting device shown in FIG. 1.

Referring to FIGS. 1 and 2, the organic light emitting device 100 according to an embodiment of the present invention includes a substrate 111, a first electrode (anode) 112, a hole injection layer (HIL) 113, a hole transport layer (HTL) 114, a buffer layer (BFL) 115, a light emitting layer (EML) 116, an electron transport layer (ETL) 117, an electron injection layer (EIL) 118 and a second electrode (cathode) 119.

The substrate 111 may be a glass substrate or a transparent plastic substrate. Although not shown, the substrate 111 may include a thin film transistor (TFT) for controlling driving of the organic light emitting device 100, and the TFT may have an active layer formed of an oxide semiconductor.

The first electrode 112 is formed on the substrate 111 and provides positively charged holes to the adjacent HIL. The first electrode 112 may be made of, for example, a conductive material such as one selected from indium oxide (InO), zinc oxide (ZnO), tin oxide (SnO), a combination thereof such as indium tin oxide (ITO) or indium zinc oxide (IZO), and a metal such as one of gold (Au), platinum (Pt), silver (Ag) and copper (Cu).

The hole injection layer 113 is formed on the first electrode 112 and serves as a buffer layer that reduces the energy barrier between the first electrode 112 and the hole transport layer 114 to facilitate injection of holes provided from the first electrode 112 into the hole transport layer 114. The hole injection layer 113 may include an organic for example, 4,4′,4″-tris(3-methylphenylphenylamino)triphenylamine (MTDATA), copper phthalocyanine (CuPc), or poly(3,4-ethylenedioxythiophene, polystyrene sulfonate) (PEDOT/PSS), but hole injection layer constituents are not limited thereto.

The hole transport layer 114 is formed on the hole injection layer 113 and transmits the holes provided from the hole injection layer 113 to the light emitting layer 116. The hole transport layer 114 may include an organic compound, for example, N,N′-diphenyl-N,N′-bis(3-methylphenyl)-N,N′-diphenylbenzidine(TPD) or N,N′-di(naphthalen-1-yl)-N,N′-diphenylbenzidine (NPB), but hole transport constituents are not limited thereto.

The buffer layer 115 is formed on the hole transport layer 114 and improves mobility of holes transmitted from the hole transport layer 114, thereby facilitating movement of the holes into the light emitting layer 116. The buffer layer 115 may include an organic compound, for example, N,N′-bis(3-methylphenyl)-N,N′-diphenylbenzidine (TPD) or N,N′-di(naphthalen-1-yl)-N,N-diphenylbenzidine (NPB), but buffer layer constituents are not limited thereto.

The light emitting layer 116 is formed on the buffer layer 115 and recombines the holes provided from the first electrode 112 with the electrons provided from the second electrode 119 to generate excitons in an exited state. The excitons deexcite from the excited state to a ground state to then emit light. The light emitting layer 116 may include an organic light emitting material. Alternatively, the light emitting layer 116 may include a host and a dopant having a color (red, green or blue). Examples of the host may include tris(8-hydroxyquinoline)aluminum (Alq₃), 4,4′-N,N′-dicarbazol-biphenyl (CBP), poly(N-vinylcarbazole) (PVK), 9,10-di(2-naphthyl)anthracene(ADN), 4,4′,4″-tri(N-carbazolyl)-triphenylamine (TCTA), 1,3,5-tris(N-phenylbenzimidazol-2-yl)benzene (TPBI), 2-tert-butyl-9,10-di(2-naphthyl) anthracene(TBADN), terfluorene (E3), and distyrylarylene but materials useful as hosts are not limited thereto. Meanwhile, platinum octaethylporphine (PtOEP), tris[1-phenylisoquinoline-C2,N]iridium(III) (Ir(piq)₃), or bis(2-(2′-benzo[4,5-a]thienyl)pyridinato-N,C3′)iridium(acetyl-acetonate)(Btp₂Ir(acac)) may be used as the red dopant, but materials useful as the red dopant are not limited thereto. In addition, one of tris(2-phenylpyridine)iridium (Ir(ppy)₃), acetylacetonatobis(2-phenylpyridine)iridium (Ir(ppy)₂(acac)), and tris[2-(4-methylpyridin-2-yl)phenyl]iridium (Ir(mpyp)₃) may be used as the green dopant, but materials useful as the green dopant are not limited thereto. Meanwhile, one of bis[2-(4,6-difluorophenyl)pyridinato-N,C-2′]iridium picolinate (F₂Irpic), bis[4-acetyl-2-(4,6-difluorophenyl)pyridinato-N,C-2′]-(2,2,6,6-tetramethylheptane-3,5-dionato)iridium ((F₂ppy)₂Ir(tmd)), tris[2-(4,6-difluorophenyl)pyrazolyl-N-1,C-2′]iridium (Ir(dfppz)₃), terfluorene, 4,4′-bis(4-diphenylaminostyryl)biphenyl (DPAVBi), and 2,5,8,11-tetra(tert-butyl)perylene(TBPe) may be used as the blue dopant, but materials useful as blue dopants are not limited thereto.

The light emitting layer 116 may be a red light emitting layer emitting red light, a green light emitting layer emitting green light, or a blue light emitting layer emitting blue light. In addition, the light emitting layer may be a white light emitting layer formed by stacking the red light emitting layer, the green light emitting layer and the blue light emitting layer and emitting white light.

The electron transport layer 117 may be formed on the light emitting layer 116 and may transmit electrons provided from the second electrode 119 to the light emitting layer 116. The electron transport layer 117 may include an organic compound, for example, one of 4,7-diphenyl-1,10-phenanthroline (Bphen), bis(2-methyl-8-quinolinato)-4-phenylphenolate aluminum (BAlq), tris(8-hydroxyquinoline)aluminum (Alq₃), bis(10-hydroxybenzo[h]quinolinato)beryllium (Bebq₂), and 1,3,5-tris(N-phenylbenzimidazol-2-yl)benzene (MN), but organic compounds useful for inclusion in the electron transport layer are not limited thereto.

The electron injection layer 118 may be formed on the electron transport layer 117 and may serve as a buffer layer that reduces an energy barrier between the electron transport layer 117 and the second electrode 119 and facilitates injection of electrons provided from the second electrode 119 into the electron transport layer 117. The electron injection layer 118 may be made of, for example, one of LiF and CsF, but is not limited thereto.

The second electrode 119 may be formed on the electron injection layer 118 and may provide electrons to the electron injection layer 118. The second electrode 119 may include a conductive material, for example, one of aluminum (Al), silver (Ag), magnesium (Mg), lithium (Li), calcium (Ca) and alloys thereof, but is not limited thereto.

The blocking layer 120 may be between the hole transport layer 114 and the buffer layer 115 so as to contact the hole transport layer 114 and the buffer layer 115. The blocking layer 120 may be formed at a location at which the electrons remaining in the light emitting layer 116 after the excitons are formed and residual excitons may be blocked from flowing into the hole transport layer 114 while the excitons contributing to light emission in the light emitting layer 116 remain unaffected. The blocking layer 120 prevents the hole transport layer 114 from being deteriorated by the electrons or residual excitons remaining in the light emitting layer 116 as a byproduct of light emission, thereby increasing the lifetime of the organic light emitting device 100. In particular, the blocking layer 120 greatly increases the lifetime of the organic light emitting device 100 when the device includes a blue light emitting layer as the light emitting layer 116.

The blocking layer 120 may include a p-type dopant. Specifically, the blocking layer 120 may be formed by doping the p-type dopant into the buffer layer 115. The blocking layer 119 may be formed at the same time as the buffer layer 115 is formed using a co-deposition method.

In order to facilitate movement of holes from the hole transport layer 114 to the light emitting layer 116 while blocking the remaining electrons or residual excitons from flowing from the light emitting layer 116 into the hole transport layer 114, the p-type dopant includes an organic material having a lowest unoccupied molecular orbital (LUMO) energy level (that is energy level required to move electrons) higher than a highest occupied molecular orbital (HOMO) energy level (that is energy level required to move holes) of the hole transport layer 114 or a highest occupied molecular orbital (HOMO) energy level (that is energy level required to move holes) of the light emitting layer 116. Here, the HOMO energy level of the light emitting layer 116 is higher than the HOMO energy level of the hole transport layer 114.

Examples of the p-type dopant may be one selected from tetracyanoquinodimethane (TCNQ), antimony pentachloride (SbCl₅), tetracyano-2,6-naphthoquinodimethane (TNAP), iron (III) chloride (FeCl₃) and tetrafluoro-tetracyanoquinodimethane (F4-TCNQ).

In addition, the blocking layer 120 may have a thickness in a range of from about 10 Å to about 1000 Å. If the blocking layer 120 has a thickness of less than 10 Å, the effect of the blocking layer 120 in blocking the remaining electrons or residual excitons may be insufficient. If the blocking layer 120 has a thickness of greater than 1000 Å, the holes provided from the hole transport layer 114 may be considerably prevented from moving to the light emitting layer 116.

In addition, the blocking layer 120 may be formed such that the p-type dopant is contained in an amount of 1 to 50% relative to an amount of a host contained in the blocking layer 120, and the host contained in the blocking layer 120 may be the same material used for forming the buffer layer 115. If the amount of the p-type dopant is less than 1% relative to the amount of the host contained in the blocking layer 120, the effect of the blocking layer 120 in blocking the remaining electrons or residual excitons may be insufficient. If the amount of the p-type dopant is greater than 50% relative to the amount of the host contained in the blocking layer 120, the blocking layer 120 may considerably prevent the holes provided from the hole transport layer 114 from moving to the light emitting layer 116.

While the aforementioned embodiment has shown that the blocking layer 120 may be formed by doping the p-type dopant in the buffer layer 115, the p-type dopant may be formed as a single layer to be interposed between the buffer layer 115 and the hole transport layer 114.

Next, the lifetime increasing effect of the organic light emitting device 100 will be described.

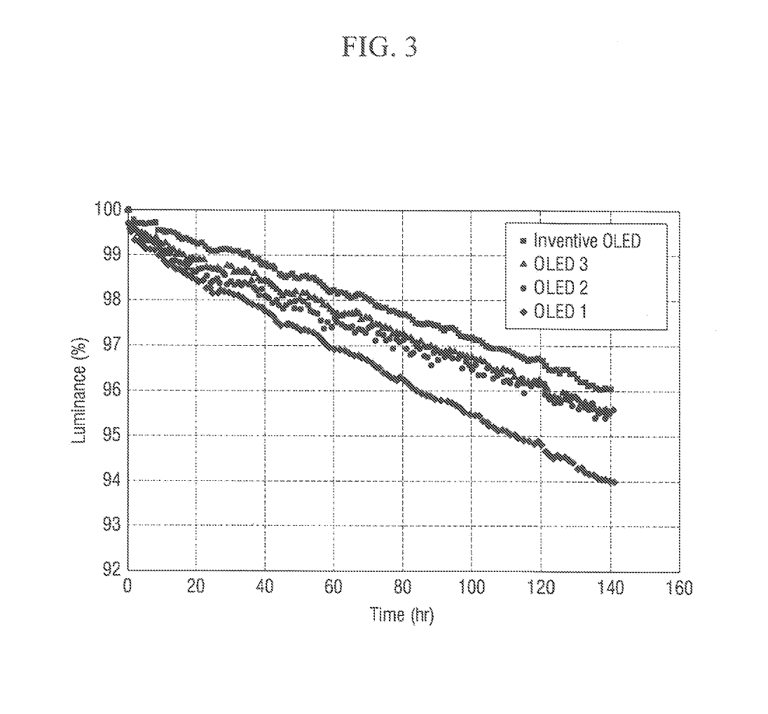

FIG. 3 is a graph illustrating results obtained from measuring lifetime characteristics of the organic light emitting device shown in FIG. 1 and other organic light emitting devices.

In FIG. 3, OLED 1 is an organic light emitting device including a substrate, a first electrode, a hole injection layer, a hole transport layer, a light emitting layer, an electron transport layer, an electron injection layer and a second electrode, OLED 2 and OLED 3 are organic light emitting devices each including a substrate, a first electrode, a hole injection layer, a hole transport layer, a buffer layer, a light emitting layer, an electron transport layer, an electron injection layer and a second electrode, and inventive OLED is an organic light emitting device including a substrate 111, a first electrode 112, a hole injection layer 113, a hole transport layer 114, a blocking layer 120, a buffer layer 115, a light emitting layer 116, an electron transport layer 117, an electron injection layer 118 and a second electrode 119, as shown in FIG. 1.

Referring to FIG. 3, the time when a luminance level of the OLED 1 is 97% is about 60 hours from the reference time when the measurement for the luminance level of the OLED 1, OLED 2, OLED 3 and the inventive OLED is begun. The time when a luminance level of each of the OLED 2 and OLED 3 is 97% is about 80 hours from the reference time. The time when a luminance level of the inventive OLED is 97% is about 100 hours from the reference time. From this, be seen that the lifetime of the inventive OLED is increased by about 40 hours compared to the lifetime of the OLED 1 based on the same luminance level. Also, it can be seen that the lifetime of the inventive OLED is increased by about 20 hours compared to the lifetime of each of the OLED 2 and OLED 3. Thus, the inventive OLED having the blocking layer 120 has a considerably enhanced lifetime characteristic in comparison with OLEDs constructed without it.

As described above, because the organic light emitting device 100 includes the blocking layer 120 between the hole transport layer 114 and the buffer layer 115 so as to contact the hole transport layer 114 and the buffer layer 115, it is possible to prevent both the electrons remaining in the light emitting layer 116 after excitons are formed and residual excitons from flowing into the hole transport layer 114.

Therefore, the organic light emitting device 100 according to the present invention can prevent the hole transport layer 114 from being deteriorated due to remaining electrons or residual excitons, thereby increasing the lifetime of the organic light emitting device 100.

Next, an organic light emitting device according to another embodiment of the present invention will be described.

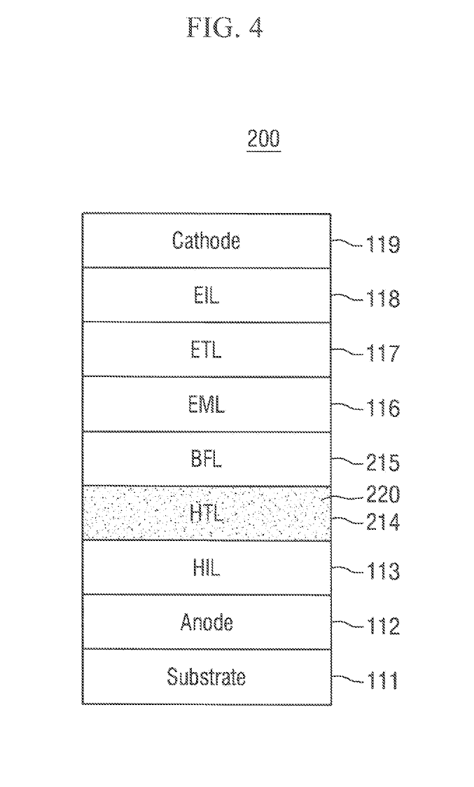

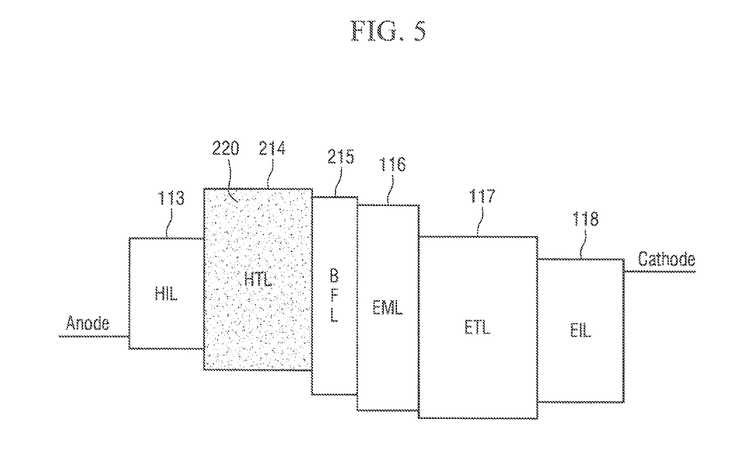

FIG. 4 is a sectional view schematically illustrating an organic light emitting device according to another embodiment of the present invention, and FIG. 5 is an energy band diagram of the organic light emitting device shown in FIG. 4.

The organic light emitting device 200 according to another embodiment of the present invention is substantially the same as the organic light emitting device 100 according to an embodiment of the present invention, except that a blocking layer 120 is not provided and a hole transport layer 214 serves as the blocking layer 120. Accordingly, the following description will focus only on differences between the organic light emitting device 200 and the organic light emitting device 100, and repeated descriptions will be omitted.

Referring to FIGS. 4 and 5, the organic light emitting device 200 includes a substrate 111, a first electrode (anode) 112, a hole injection layer (HIL) 113, a hole transport layer (HTL) 214, a buffer layer (BFL) 215, a light emitting layer (EML) 116, an electron transport layer (ETL) 117, an electron injection layer (EIL) 118 and a second electrode (cathode) 119.

The hole transport layer 214 is similar to the hole transport layer 114 shown in FIG. 1. The hole transport layer 214 may include the blocking material 220 for blocking both the electrons remaining in the light emitting layer 116 after the excitons are formed and residual excitons from flowing into the hole transport layer 114. The blocking material 220 may be the same as the p-type dopant contained in the blocking layer 120 shown in 1. The p-type dopant includes an organic material having a lowest unoccupied molecular orbital (LUMO) energy level higher than a highest occupied molecular orbital (HOMO) energy level of the hole transport layer 214 or a highest occupied molecular orbital energy level of the light emitting layer 116. Here, the HOMO energy level of the light emitting layer 116 is higher than the HOMO energy level of the hole transport layer 214.

Examples of the p-type dopant may be one selected from tetracyanoquinodimethane (TCNQ), antimony pentachloride (SbCl₅), tetracyano-2,6-naphthoquinodimethane (TNAP), iron (III) chloride (FeCl₃) and tetrafluoro-tetracyanoquinodimethane (F4-TCNQ).

Advantageously, since the p-type dopant is doped into the hole transport layer 214 far from the light emitting layer 116 through the buffer layer 215, it does not greatly affect the excitons of the light emitting layer 116. Accordingly, the p-type dopant may be formed at any location within the hole transport layer 214 without any particular limitation.

The buffer layer 215 is similar to the buffer layer 115 shown in FIG. 1. The buffer layer 215 is different from the buffer layer 115 shown in FIG. 1 in that the blocking layer 120 formed by doping the p-type dopant into the buffer layer 115 and shown in FIG. 1 is not provided.

As described above, since the organic light emitting device 200 according to another embodiment of the present invention includes the blocking material 220 contained in the hole transport layer 214, it is possible to prevent both the electrons remaining in the light emitting layer 116 after the excitons are formed and residual excitons from flowing into the hole transport layer 214.

Therefore, the organic light emitting device 200 according to the present invention may prevent the hole transport layer 214 from being deteriorated due to remaining electrons or residual excitons, thereby increasing the lifetime of the organic light emitting device 200.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. An organic light emitting device comprising:
a substrate;
a first electrode formed on the substrate;
a hole injection layer formed on the first electrode;
a hole transport layer formed on the hole injection layer;
a buffer layer formed on the hole transport layer;
a light emitting layer formed on the buffer layer;
an electron transport layer formed on the light emitting layer;
an electron injection layer formed on the electron transport layer;
a second electrode formed on the electron injection layer; and
a blocking layer formed between the hole transport layer and the buffer layer so as to contact the hole transport layer and the buffer layer.

2. The organic light emitting device of claim 1, the blocking layer including a p-type dopant.

3. The organic light emitting device of claim 2, a lowest unoccupied molecular orbital (LUMO) energy level of the p-type dopant being higher than a highest occupied molecular orbital (HOMO) energy level of the hole transport layer and higher than a highest occupied molecular orbital (HOMO) energy level of the light emitting layer, and the HOMO energy level of the light emitting layer being higher than the HOMO energy level of the hole transport layer.

4. The organic light emitting device of claim 1, the blocking layer being formed by doping a p-type dopant into the buffer layer.

5. The organic light emitting device of claim 4, the p-type dopant being contained in an amount of from 1 to 50% relative to an amount of a host contained in the blocking layer, the host contained in the blocking layer being a material used for forming the buffer layer.

6. The organic light emitting device of claim 1, the blocking layer being configured by forming the p-type dopant as a single layer and being interposed between the buffer layer and the hole transport layer.

7. The organic light emitting device of claim 1, the blocking layer having a thickness in a range of from about 10 Å to about 1000 Å.

8. The organic light emitting device of claim 1, the light emitting layer being one of a red light emitting layer, a green light emitting layer, a blue light emitting layer and a white light emitting layer.

9. The organic light emitting device of claim 8, the white light emitting layer being formed by stacking the red light emitting layer, the green light emitting layer and the blue light emitting layer.

10. An organic light emitting device comprising:
a substrate;
a first electrode formed on the substrate;
a hole injection layer formed on the first electrode;
a hole transport layer formed on the hole injection layer;
a buffer layer formed on the hole transport layer;
a light emitting layer formed on the buffer layer;
an electron transport layer formed on the light emitting layer;
an electron injection layer formed on the electron transport layer; and
a second electrode formed on the electron injection layer,
the hole transport layer including a blocking material.

11. The organic light emitting device of claim 10, the blocking material being a p-type dopant.

12. The organic light emitting device of claim 11, a lowest unoccupied molecular orbital (LUMO) energy level of the p-type dopant being higher than a highest occupied molecular orbital (HOMO) energy level of the hole transport layer and higher than a highest occupied molecular orbital (HOMO) energy level of the light emitting layer, the HOMO energy level of the light emitting layer being higher than the HOMO energy level of the hole transport layer.

13. The organic light emitting device of claim 10, the light emitting layer being one of a red light emitting layer, a green light emitting layer, a blue light emitting layer and a white light emitting layer.

14. The organic light emitting device of claim 13, the white light emitting layer being formed by stacking the red light emitting layer, the green light emitting layer and the blue light emitting layer.
